(19) United States
(12) Patent Application Publication
(10) Pub. No.: US 2023/0266392 A1
(43) Pub. Date: Aug. 24, 2023

(54) MULTI-OBJECTIVE SIMULTANEOUS CHARGING METHOD FOR LITHIUM-ION BATTERY PACKS

(71) Applicant: ZHEJIANG UNIVERSITY, Zhejiang (CN)

(72) Inventors: Jian CHEN, Zhejiang (CN); Hao CHEN, Zhejiang (CN); Xiaodong FAN, Zhejiang (CN); Mi ZHOU, Zhejiang (CN); Yuan FU, Zhejiang (CN)

(73) Assignee: ZHEJIANG UNIVERSITY, Zhejiang (CN)

(21) Appl. No.: 17/793,417

(22) PCT Filed: Jun. 29, 2020
(86) PCT No.: PCT/CN2020/098782

§ 371 Date: Nov. 14, 2022

(30) Foreign Application Priority Data
Jan. 17, 2020 (CN) 202010054218.0

(51) Int. Cl. G01R 31/367; G01R 31/378; H02J 7/00

(52) U.S. Cl. CPC G01R 31/367; G01R 31/378; H02J 7/00712; H02J 7/0048

(57) ABSTRACT

Disclosed in the present invention is a multi-target simultaneous charging method for a lithium battery pack: converting energy loss and charging current into a lithium battery pack charging cost model with a charging weight coefficient, and using an interior point method for solving and processing to acquire a preset charging current sequence; on the basis of the preset charging current sequence, calculating the charging time required when charging the lithium battery pack, and adjusting the charging weight coefficient in the lithium battery pack charging cost model by means of an adaptive momentum gradient descent algorithm to obtain the charging weight coefficient with the shortest charging time; using the charging weight coefficient to optimize the lithium battery pack charging cost model to acquire a new preset charging current sequence; and using the new preset charging current sequence to implement charging, thereby implementing optimized multi-target simultaneous charging of the lithium battery pack.

### TECHNICAL FIELD

The disclosure belongs to a lithium battery charging method in the field of lithium battery application, and particularly relates to a multi-target simultaneous charging method for a lithium battery pack.

### DESCRIPTION OF RELATED ART

Lithium batteries have the advantages of high power density, high energy density, long cycle life, high output voltage, being environmentally friendly, and therefore they are widely used in various fields. Currently, how to improve the charging rate, service life and usable capacity of lithium batteries are popular research topics. At present, there are many charging methods for lithium batteries. The conventional charger has a single charging mode and fixed parameters, and the real state of the battery is not taken into consideration, therefore the battery is damaged in the charging process. The charging and discharging process of lithium batteries is an electrochemical reaction process, and the charging properties of lithium batteries are related to various factors such as the internal structure of the battery, charging parameters, and external environment. The charging process takes place along with polarization effects and internal temperature changes.

Studies have shown that there is an optimal charging curve for lithium batteries. When a charging curve is close to the optimal charging curve, the charging speed is the fastest, the efficiency is the highest, and the battery damage is minimal. The smart charging method for lithium battery is a relatively advanced charging method at present. Such method may adjust the charging current in real time by detecting the battery state parameters, and dynamically track the optimal charging curve, thereby realizing the fast and friendly charging of the lithium battery. However, this method is prone to overcurrent charging in the early stage of charging, while the current is small and the efficiency is low at the end of charging. The conventional charging methods of lithium batteries mainly include constant current charging, constant voltage charging, pulse charging, relax charging and so on. Mas. J. A provides the concept that instantaneous charging or high-current discharge can eliminate the polarization phenomenon and make the acceptable charging curve of the battery continuously shift to the right, thereby improving the charging efficiency, which is a theoretical basis for speeding up the charging speed. At present, the most commonly used charging method is a three-stage charging method, which has problems such as slow charging speed, low efficiency, and inability to eliminate the polarization phenomenon during battery charging.

### SUMMARY

In order to solve the problems existing in the related art, the present disclosure provides a multi-target simultaneous charging method for lithium batteries. During the charging process, the actual charging state may converge to the same value in the shortest time, and the time difference between the charging time and the convergence time is minimized simultaneously, so as to achieve more efficient charging.

As shown in FIG. 1, the technical solution adopted in the present disclosure is:

Each single cell of a lithium battery pack will have some energy loss due to its own internal resistance during charging. Considering the constraints of the charging current when charging the lithium battery, the charging weight coefficient is added to convert the energy loss and charging current into a lithium battery pack charging cost model having a charging weight coefficient. Then, the lithium battery pack charging cost model is expressed as a quadratic programming problem, and an interior point method is adopted to solve the quadratic programming problem to obtain a preset charging current sequence.

Then, according to the preset charging current sequence, the charging time required for charging the lithium battery pack is calculated, and the charging weight coefficient in the lithium battery pack charging cost model is adjusted through the adaptive momentum gradient descent algorithm to obtain the charging weight coefficient within the shortest charging time. The charging weight coefficient is utilized to optimize the lithium battery pack charging cost model to acquire a new preset charging current sequence. The new preset charging current sequence is adopted to implement charging. In this way, the charging process and the convergence process may be completed simultaneously, thereby implementing optimized multi-target simultaneous charging of the lithium battery pack.

During the charging process of the present disclosure, the actual charging state may converge to the same value in the shortest time, while the time difference between the charging time and the convergence time is minimized.

The process of method is specifically as follows:

Step 1: The lithium battery pack is composed of n independent single cells. According to the basic dynamic characteristics of the lithium battery, an equivalent circuit model of the lithium battery pack is established, and the model parameters are determined by using the experimental data obtained from the realization of the known conditions in advance. The model parameters include the capacity Q of the lithium battery, the internal R₀ resistance of the lithium battery and the charging efficiency η.

Step 3: The charging target is set, including setting the estimated charging time and the preset charging SOC. Consider that the temperature of each single cell during the charging process is controlled to be low, and at the same time, the battery should be balanced during the charging process, the charging weight coefficient is introduced, and a lithium battery pack charging cost model including preset charging SOC, battery temperature and battery balance is established.

Step 4: The lithium battery pack charging cost model in Step 3 is taken as a constrained quadratic programming problem, and a quadratic programming solution method (such as an interior point method) is adopted to solve the lithium battery pack charging cost model to obtain the preset charging time and the preset charging current u_{i,k} of each single cell at each moment under the preset charging SOC, thereby forming an optimal charging current sequence, and the lithium battery pack is controlled with the optimal charging current sequence for charging.

Step 5: Real-time detection of the SOC x_{j,k} of each single cell in the real-time state of the charging process is performed under the control of step 4. The convergence time T₁(ε₁) and charging time T₂(ε₂) are obtained according to the following formula, and the following simultaneous charging time function is established.

$${min}_{x} {f}_{4} ( x ) = max \{ {T}_{1} ( {ε}_{1} ) , {T}_{2} ( {ε}_{2} ) \} \\ {T}_{1} ( {ε}_{1} ) = min \{ τ ‖ {x}_{i} ( k ) - {x}_{j} ( k ) ‖ \leq {ε}_{1} , ∀ k \geq τ / T , ∀ i , j \} \\ {T}_{2} ( {ε}_{2} ) = min \{ τ ‖ x ( k ) - {χ}_{d} ‖ \leq {ε}_{2} , ∀ k \geq τ / T \}$$

In the formula, T₁(ε₁), T₂(ε₂) represent the convergence time and charging time, respectively, xᵢ(k) and xⱼ(k) represent the value of state of charge (SOC) of the i-th single cell of the lithium battery pack at time k, ε₁ and ε₂ represent the cut-off error of the convergence process and the charging process, respectively, T represents the sampling time, τ represents the time variable, i and j represent the ordinal numbers of the single cells in the lithium battery pack, and χ_{d} represents the column vector of the expected value of the SOC of the single cell, which is a n×1 column vector composed of the expected value of the SOC of the single cell.

The adaptive momentum gradient descent algorithm is adopted to process the simultaneous charging time function, optimize the first weight coefficient α and the second weight coefficient β in the lithium battery pack charging cost model, and return to step 3 for update. The updated expression of the first weight coefficient α and the second weight coefficient β is:

$$Δ α ( k ) = - ω ( k ) ( 1 - θ ) ∇ T ( k ) + θΔα ( k - 1 ) \\ Δβ ( k ) = - ω ( k ) ( 1 - θ ) ∇ T ( k ) + θΔβ ( k - 1 ) \\ ω ( k + 1 ) = \{ \begin{matrix}λω ( k ) , ∇ T ( k ) \geq μ ∇ T ( k - 1 ) \\ 1 / λ ω ( k ) , ∇ T ( k ) \leq 1 / μ ∇ T ( k - 1 ) \\ ω ( k ) , Other conditions\end{matrix}$$

In the formula, Δα(k), Δα(k−1) represent the increments of α at times k and k−1, respectively, Δβ(k), Δβ(k−1) represent the increments of β at times k and k−1, respectively, ∇T(k), ∇T(k−1) represent the increments of the simultaneous charging time T at times k and k−1, respectively, where the simultaneous charging time T=max {T₁(ε₁), T₂(ε₂)}, θ represents momentum factor, ω(k) represents the adaptive learning rate. Then step 4 is repeated for processing, and the optimal charging current sequence obtained after update is adopted to control the charging of the lithium battery pack.

The disclosure provides a multi-target optimization method for simultaneous battery charging based on quadratic programming and adaptive momentum gradient descent algorithm for lithium battery packs composed of multiple single cells by taking into consideration the energy loss and charging mode of the lithium battery pack itself. The method is carried out to minimize the influence of the current on the battery while ensuring the charging efficiency.

In the step 1, a single cell equivalent circuit is established for each single cell of the lithium battery pack, and the single cell equivalent circuit includes a capacitor Cb, a constant voltage source Vsoc, a voltage controlled voltage source Voc and an internal resistance R₀. The voltage-controlled voltage source Voc is an SOC equivalent circuit composed of a capacitor Cb and a constant voltage source Vsoc arranged in parallel. The SOC equivalent circuit is configured to simulate the SOC change of a single cell. The voltage-controlled voltage source Voc and the internal resistance R₀ are connected in series to form a voltage equivalent circuit. The voltage equivalent circuit is configured to simulate the voltage change of a single cell.

In the step 1, the equivalent circuit model of the single cell of the lithium battery pack is expressed by the following formula:

$${V}_{{SOC}_{i}} ( k + 1 ) = {V}_{{SOC}_{i}} ( k ) - \frac{η {TI}_{{B}_{i}} ( k )}{Q} \\ {V}_{{B}_{i}} ( k ) = {V}_{{OC}_{i}} ( k ) - {R}_{0} {I}_{{B}_{i}} ( k )$$

In the formula, V_{SOC}_{ᵢ}(k+1) and V_{SOC}_{ᵢ}(k) represent the value of state of charge (SOC) of the i-th single cell of the lithium battery pack at times k+1 and k, respectively, η represents the charging efficiency, T represents the sampling time, and I_{B}_{ᵢ}(k) represents the charging current value of the i-th single cell at time k, Q represents the capacity of the single cell of the lithium battery pack, R₀ represents the internal resistance of the single cell of the lithium battery pack, V_{B}_{ᵢ}(k) and V_{OC}_{ᵢ}(k) represent the output terminal voltage and open circuit voltage of the i-th single cell at time k, respectively.

In the step 3, the following lithium battery pack charging cost model is established:

$${min}_{x} F ( x ) = {f}_{1} ( x ) + α {f}_{2} ( x ) + β {f}_{3} ( x ) \\ {f}_{1} ( x ) = {\sum }_{k = 1}^{m} {\sum }_{j = 1}^{n} {\sum }_{i = 1}^{n} {( {x}_{i , k} - {x}_{j , k} )}^{2} \\ {f}_{2} ( x ) = {\sum }_{k = 1}^{m} {\sum }_{i = 0}^{n - 1} {{R}_{0} ( {u}_{i , k} - {d}_{k} )}^{2} \\ {f}_{3} ( x ) = {\sum }_{k = 1}^{m} {\sum }_{i = 1}^{n} {( {x}_{i , k} - {x}_{d} )}^{2}$$

In the formula, F(x) represents the vector of the lithium battery pack charging cost model, f₁(x) represents the sum of the SOC deviations between the single cells, and it is expected that the SOC of each single cell can converge to the same during the charging process; f₂(x) represents the energy loss generated due to internal resistance inside the lithium battery during the charging process, f₃(x) represents the sum of the deviations of the single cells charged to the same value, f₄(x) represents the charging time; α represents the first weight coefficient, β represents the second weight coefficient, x_{i,k} represents the SOC of the i-th single cell at time k, x_{j,k} represents the SOC of the j-th single cell at time k, u_{i,k} represents the charging current of the i-th single cell at time k, dₖ represents the disturbance current at time k, x_{d} represents the expected value of the SOC of the single cell, i and j represent the ordinal number of the single cell in the lithium battery pack, n is the total number of single cells in the lithium battery pack, and m is the number of charging steps.

The charging weight coefficients of the three sub-targets of the lithium battery pack charging cost model are determined by simultaneous charging time.

In the meantime, the constraints in the charging process are established, including:

(1) The SOC column vector SOC(k) of the battery connected in series in the battery pack at time k satisfies:

SOC(k)≤SOCᵤ

In the formula, SOC(k) and SOCᵤ are both column vectors of length n, and SOCᵤ represents the upper limit value of the SOC of the lithium battery pack.

(2) The charging current column vector I(k) of each single cell in the battery pack at time k satisfies:

I/(k)≤I_{M}

In the formula, I(k) and I_{M} are both column vectors of length n, and I_{M} represents the upper limit value of the charging current of each single cell in the lithium battery pack.

(3) The terminal voltage column vector U(k) of each single cell in the battery pack at time k satisfies:

U(k)≤U_{M}

In the formula, U(k) and U_{M} are both column vectors of length n, and U_{M} represents the upper limit value of the terminal voltage of each single cell of the lithium battery pack.

During the charging process of the method, the terminal voltage of each single cell in the lithium battery pack is detected in real time. If the terminal voltage of any single cell exceeds the preset maximum open circuit voltage of the battery (normally 4.2 V), the preset charging current in the optimal charging current sequence obtained in step 4 is reduced (in specific implementation, the preset charging current may be reduced by 5%).

For a lithium battery pack, the present disclosure calculates the initial SOC of each single cell by measuring the initial open circuit voltage. According to the charging cost model in claim 5, a quadratic programming algorithm is adopted to calculate the preset charging current sequence. The lithium battery pack is continuously charged according to the preset charging current sequence obtained through calculation, and then the convergence time and charging time are calculated to obtain the simultaneous charging time. According to the adaptive momentum gradient descent algorithm, the first weight coefficient α and the second weight coefficient β in the lithium battery pack charging cost model are continuously optimized, so that the simultaneous charging time is minimized.

The advantageous effects of the present disclosure are:

1) The present disclosure significantly reduces the error of charging time and convergence time, thereby maximally reducing the influence of current on the battery while ensuring charging efficiency. 2) The present disclosure provides a control strategy for the simultaneous charging of lithium battery packs, so that the lithium battery packs may be fully charged simultaneously, and different charging rates may be applied to single cells with different SOCs. Also, the damage to the lithium battery packs may be reduced with as little current as possible, so as to improve the health status of the lithium battery pack itself. 3) The charging strategy comprehensively takes into consideration the constraints of the lithium battery pack itself, energy loss and simultaneous charging time to achieve simultaneous optimization of multiple targets.

### BRIEF DESCRIPTION OF THE DRAWINGS

FIG. 1 is a schematic diagram of a simultaneous charging structure of lithium batteries in the present disclosure.

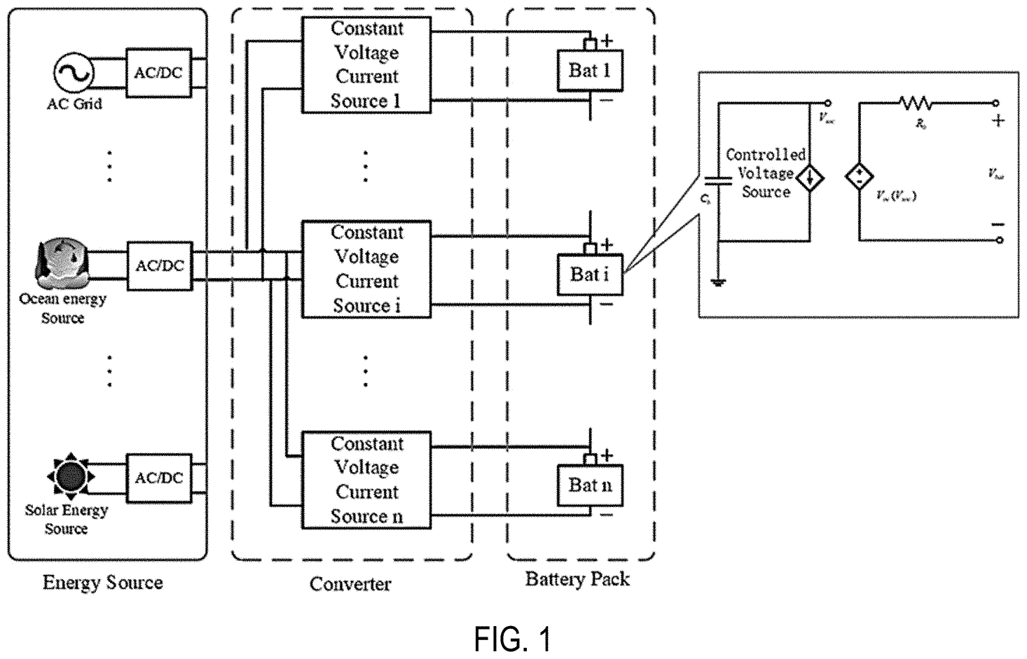

FIG. 2 is a graph showing a state of charge variation under a given weight coefficient in an embodiment of the present disclosure.

FIG. 3 is a graph showing the variation of an actual value of a charging current under a given weight coefficient in an embodiment of the present disclosure.

FIG. 4 is a graph showing a state of charge variation optimized by an adaptive momentum gradient descent algorithm in an embodiment of the present disclosure.

FIG. 5 is a graph showing the variation of an actual value of a charging current optimized by the adaptive momentum gradient descent algorithm in an embodiment of the present disclosure.

FIG. 6 is a graph showing the change curves of simultaneous charging time and two weight coefficients optimized by the adaptive momentum gradient descent algorithm in an embodiment of the present disclosure.

### DESCRIPTION OF THE EMBODIMENTS

The present disclosure will be further described below with reference to the accompanying drawings and embodiments.

Embodiments implemented according to the method of the present disclosure are as follows:

The lithium battery pack for this experiment consists of four lithium batteries. The capacity and nominal voltage of the battery are 3100 mAh and 3.7V, respectively. The current operating range of the battery is [−1 A, 0], the sampling time is T=1 s, and the upper and lower limits of the SOC are set to 100% and 5%. The initial SOC of each battery in the battery pack is:

SOC₁(0)=51%, SOC₂(0)=60%, SOC₃(0)=50%, SOC₄(0)=62%.

In this embodiment, through the global optimization control setting, if the SOC difference between any two single cells is less than 0.1%, the battery charging process will stop.

2. Experimental Results

In this embodiment, the preset charging current sequence is obtained by real-time calculation to charge the lithium battery pack. The abscissa represents the time (unit of measurement is seconds), the ordinate represents the SOC of the battery, and the four lines with marks respectively represent the real-time SOC of the four single cells, which are respectively denoted as battery 1 . . . battery 4.

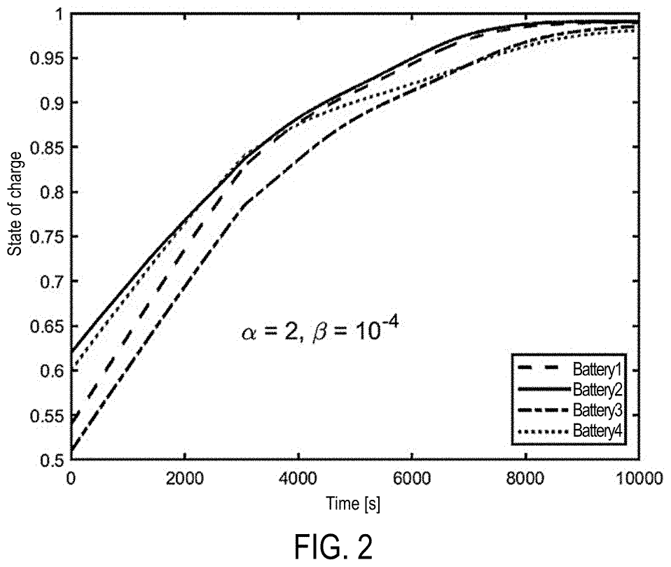

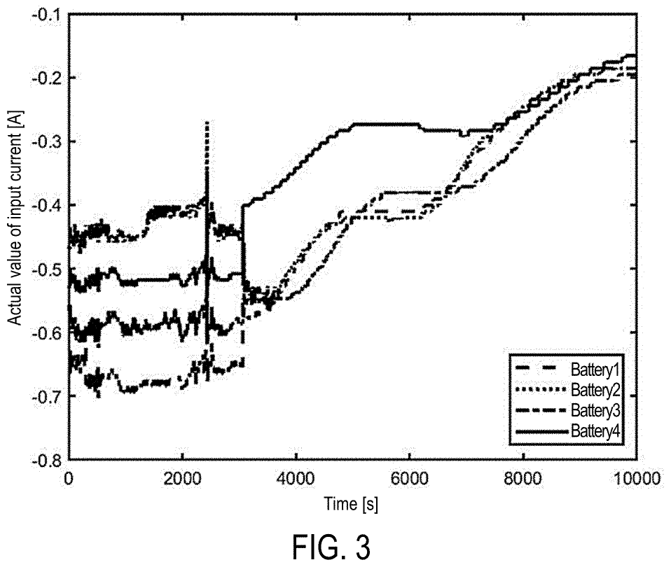

FIG. 2 and FIG. 3 respectively show the change of SOC and the change of charging current of the lithium battery pack obtained through quadratic programming under the given first weight coefficient α and second weight coefficient β, and α=2, β=10⁻⁴. Under the circumstances, the charging time is close to 10000 seconds, the convergence time is 9562 seconds, and the relative error is close to 5%.

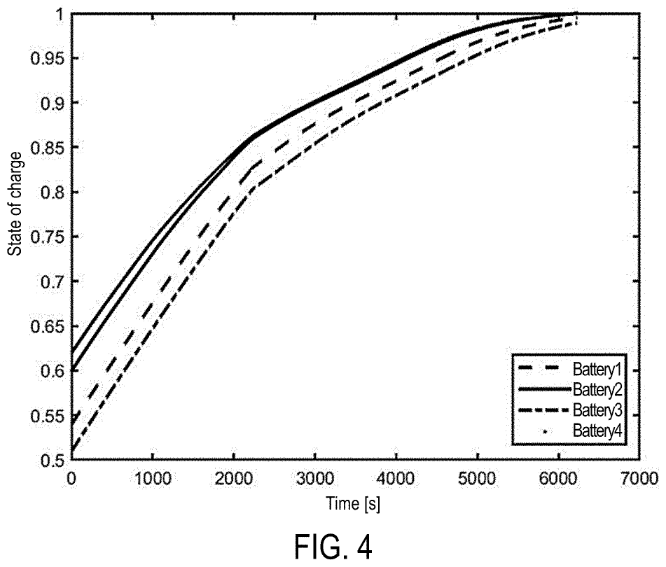

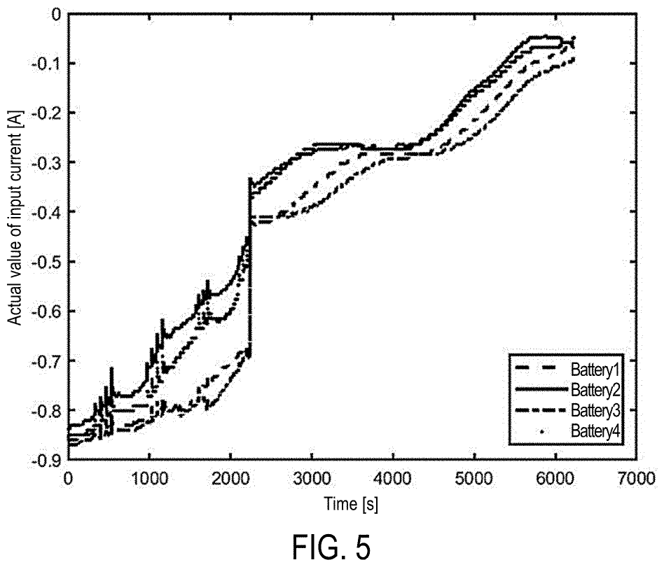

FIG. 4 and FIG. 5 show the changes in the SOC and charging current of the lithium battery pack after the adaptive momentum gradient descent algorithm is adopted to optimize the first weight coefficient α and the second weight coefficient β. The charging time and the convergence time are 5583s and 5533s, respectively. Therefore, during the charging process, the charging time and the convergence time are significantly shortened. In the meantime, the relative time error between the charging time and the convergence time is also minimized by less than 1%, so that it may be ensured that the lithium battery pack is fully charged simultaneously and the required time is the shortest. In this way, batch charging of lithium battery packs is realized, the charging current of lithium batteries is limited in the shortest charging time, so that protection for lithium batteries may be achieved.

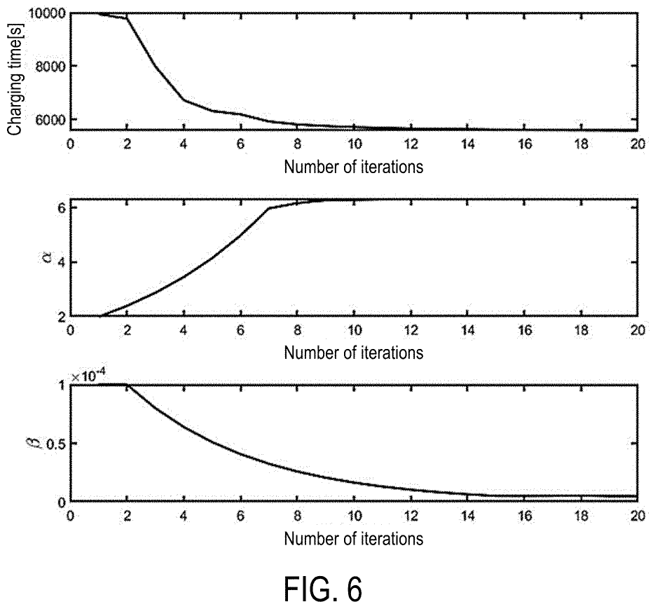

FIG. 6 shows that under the optimization of the adaptive momentum gradient descent algorithm, the simultaneous charging time is significantly shortened, and also shows the corresponding change of the first weighting coefficient α and second weighting coefficient β. It can be seen from FIG. 6 that under the effect of the adaptive momentum gradient descent algorithm, the two weight coefficients are continuously updated to appropriate values to shorten the simultaneous charging time, and the adaptive adjustment term is added to the gradient descent algorithm to ensure the convergence speed of the algorithm. As shown in FIG. 6, the convergence process has been completed under the number of iterations not exceeding 20 steps.

1. A multi-target simultaneous charging method for a lithium battery pack, wherein considering constraints of a charging current when charging a lithium battery, a charging weight coefficient is added to convert an energy loss and the charging current into a lithium battery pack charging cost model having the charging weight coefficient, an interior point method is adopted for solution processing to obtain a preset charging current sequence; next, according to the preset charging current sequence, a charging time required for charging the lithium battery pack is calculated, and the charging weight coefficient in the lithium battery pack charging cost model is adjusted through an adaptive momentum gradient descent algorithm to obtain the charging weight coefficient within a shortest charging time, the charging weight coefficient is utilized to optimize the lithium battery pack charging cost model to acquire a new preset charging current sequence, the new preset charging current sequence is adopted to implement charging, thereby implementing optimized multi-target simultaneous charging of the lithium battery pack.

2. The multi-target simultaneous charging method for the lithium battery pack according to claim 1, wherein a process of the method is as follows:
step 1: the lithium battery pack is composed of n independent single cells, according to basic dynamic characteristics of the lithium battery, an equivalent circuit model of the lithium battery pack is established, and model parameters are determined by using experimental data;
step 2: a charging target comprising an estimated charging time and a preset charging SOC (state of charge) is set, the lithium battery pack charging cost model comprising the preset charging SOC, a battery temperature and a battery balance is established;
step 3: a quadratic programming solution method is adopted to solve the lithium battery pack charging cost model to obtain a preset charging current u_{i,k} of each of the single cells at each moment under the estimated charging time and the preset charging SOC, thereby forming an optimal charging current sequence, and the lithium battery pack is controlled with the optimal charging current sequence for charging;
step 4: real-time detection of a SOC x_{j,k} of each of the single cells in a real-time state of a charging process is performed under the control of step 3, a convergence time T₁(ε₁) and a charging time T₂(ε₂) are obtained according to the following formula, and a simultaneous charging time function is established as follows:
$${min}_{x} {f}_{4} ( x ) = max \{ {T}_{1} ( {ε}_{1} ) , {T}_{2} ( {ε}_{2} ) \} \\ {T}_{1} ( {ε}_{1} ) = min \{ τ ‖ {x}_{i} ( k ) - {x}_{i} ( k ) ‖ \leq {ε}_{1} , ∀ k \geq τ / T , ∀ i , j \} \\ {T}_{2} ( {ε}_{2} ) = min \{ τ ‖ x ( k ) - {χ}_{d} ‖ \leq {ε}_{2} , ∀ k \geq τ / T \}$$
wherein, T₁(ε₁), T₂(ε₂) represent the convergence time and the charging time, respectively, xᵢ(k) and xⱼ(k) represent a value of the SOC of the i-th single cell of the lithium battery pack at a time k, ε₁ and ε₂ represent a cut-off error of a convergence process and a charging process, respectively, T represents a sampling time, τ represents a time variable, i and j represent ordinal numbers of the single cells in the lithium battery pack, and χ_{d} represents a column vector of an expected value of the SOC of the single cell, which is a n×1 column vector composed of the expected value of the SOC of the single cell,
the adaptive momentum gradient descent algorithm is adopted to process the simultaneous charging time function, optimize a first weight coefficient α and a second weight coefficient β in the lithium battery pack charging cost model, and return to step 2 for update, an updated expression of the first weight coefficient α and the second weight coefficient β is:
$$Δα ( k ) = - ω ( k ) ( 1 - θ ) ∇ T ( k ) + θΔα ( k - 1 ) \\ Δβ ( k ) = - ω ( k ) ( 1 - θ ) ∇ T ( k ) + θΔβ ( k - 1 ) \\ ω ( k + 1 ) = \{ \begin{matrix}λω ( k ) , ∇ T ( k ) \geq μ ∇ T ( k - 1 ) \\ 1 / λ ω ( k ) , ∇ T ( k ) \leq 1 / μ ∇ T ( k - 1 ) \\ ω ( k ) , Other conditions\end{matrix}$$
wherein Δα(k), Δα(k−1) represent increments of α at times k and k−1, respectively, Δβ(k), Δβ(k−1) represent increments of β at times k and k−1, respectively, ∇T(k), ∇T(k−1)represent increments of a simultaneous charging time T at the times k and k−1, respectively, wherein the simultaneous charging time T=max {T₁(ε₁), T₂(ε₂)}, θ represents a momentum factor, ω(k) represents an adaptive learning rate; and step 3 is repeated for processing, and an optimal charging current sequence obtained after update is adopted to control charging of the lithium battery pack.

3. The multi-target simultaneous charging method for the lithium battery pack according to claim 2, wherein in the step 1, a single cell equivalent circuit is established for each of the single cells of the lithium battery pack, and the single cell equivalent circuit comprises a capacitor Cb, a constant voltage source Vsoc, a voltage controlled voltage source Voc and an internal resistance R₀, wherein the voltage-controlled voltage source Voc is an SOC equivalent circuit composed of the capacitor Cb and the constant voltage source Vsoc arranged in parallel, the SOC equivalent circuit is configured to simulate a SOC change of the single cell; the voltage-controlled voltage source Voc and the internal resistance R₀ are connected in series to form a voltage equivalent circuit, and the voltage equivalent circuit is configured to simulate a voltage change of the single cell.

4. The multi-target simultaneous charging method for the lithium battery pack according claim 2, wherein in the step 1, the equivalent circuit model of the single cell of the lithium battery pack is expressed by the following formula:
$${V}_{{SOC}_{i}} ( k + 1 ) = {V}_{{SOC}_{i}} ( k ) - \frac{η {TI}_{{B}_{i}} ( k )}{Q} \\ {V}_{{B}_{i}} ( k ) = {V}_{{OC}_{i}} ( k ) - {R}_{0} {I}_{{B}_{i}} ( k )$$
wherein V_{SOC}_{ᵢ}(k+1) and V_{SOC}_{ᵢ}(k) represent a value of the SOC of the i-th single cell of the lithium battery pack at times k+1 and k, respectively, η represents a charging efficiency, T represents the sampling time, and I_{B}_{ᵢ}(k) represents a charging current value of the i-th single cell at the time k, Q represents a capacity of the single cell of the lithium battery pack, R₀ represents an internal resistance of the single cell of the lithium battery pack, V_{B}_{ᵢ}(k) and V_{OC}_{ᵢ}(k) represent an output terminal voltage and an open circuit voltage of the i-th single cell at the time k, respectively.

5. The multi-target simultaneous charging method for the lithium battery pack according to claim 2, wherein
in the step 2, the following lithium battery pack charging cost model is established:
$${min}_{x} F ( x ) = {f}_{1} ( x ) + α {f}_{2} ( x ) + β {f}_{3} ( x ) \\ {f}_{1} ( x ) = {\sum }_{k = 1}^{m} {\sum }_{j = 1}^{n} {\sum }_{i = 1}^{n} {( {x}_{i , k} - {x}_{j , k} )}^{2} \\ {f}_{2} ( x ) = {\sum }_{k = 1}^{m} {\sum }_{i = 0}^{n - 1} {{R}_{0} ( {u}_{i , k} - {d}_{k} )}^{2} \\ {f}_{3} ( x ) = {\sum }_{k = 1}^{m} {\sum }_{i = 1}^{n} {( {x}_{i , k} - {x}_{d} )}^{2}$$
wherein, F(x) represents a vector of the lithium battery pack charging cost model, f₁(x) represents a sum of SOC deviations between the single cells; f₂(x) represents the energy loss generated due to an internal resistance inside the lithium battery during the charging process, f₃(x) represents a sum of deviations of the respective single cells charged to the same value, f₄(x) represents the charging time; α represents the first weight coefficient, β represents the second weight coefficient, x_{i,k} represents the SOC of the i-th single cell at the time k, x_{j,k} represents the SOC of the j-th single cell at the time k, u_{i,k} represents a charging current of the i-th single cell at the time k, dₖ represents a disturbance current at the time k, x_{d} represents an expected value of the SOC of the single cell, i and j represent ordinal numbers of the single cell in the lithium battery pack, n is a total number of the single cells in the lithium battery pack, and m is the number of charging steps;
the constraints in the charging process are established, comprising:
(1) a SOC column vector SOC(k) of batteries connected in series in the lithium battery pack at the time k satisfies:
SOC(k)≤SOCᵤ
wherein SOC(k) and SOCᵤ are both column vectors of a length n, and SOCᵤ represents an upper limit value of the SOC of the lithium battery pack;
(2) a charging current column vector I(k) of each of the single cells in the lithium battery pack at the time k satisfies:
I(k)≤I_{M}
wherein I(k) and I_{M} are both the column vectors of the length n, and I_{M} represents an upper limit value of the charging current of each of the single cells in the lithium battery pack;
(3) a terminal voltage column vector U(k) of each of the single cells in the lithium battery pack at the time k satisfies:
U(k)≤U_{M}
wherein U(k) and U_{M} are both the column vectors of the length n, and U_{M} represents an upper limit value of a terminal voltage of each of the single cells of the lithium battery pack.

6. The multi-target simultaneous charging method for the lithium battery pack according to claim 2, wherein
during the charging process of the method, a terminal voltage of each of the single cells in the lithium battery pack is detected in real time, if the terminal voltage of the single cell exceeds a preset maximum open circuit voltage of a battery, the preset charging current in the optimal charging current sequence obtained in step 3 is reduced.
